(19) United States
(12) Patent Application Publication
(10) Pub. No.: US 2026/0150630 A1
(43) Pub. Date: May 28, 2026

(54) METHOD FOR FORMING STACKED SEMICONDUCTOR STRUCTURE

(71) Applicant: Tokyo Election Limited, Tokyo (JP)

(72) Inventors: Angelique Raley, Albany, NY (US); Arkalgud Sitaram, Albany, NY (US)

(21) Appl. No.: 18/956,960

(22) Filed: Nov. 22, 2024

(51) Int. Cl. H01L 21/66; H01L 23/00

(52) U.S. Cl. CPC H10P 74/273; H10W 70/60; H10W 72/019; H10W 72/01953; H10W 72/952; H10W 90/792

(57) ABSTRACT

A method includes forming a first die in a first wafer. The first die includes first bond pads and one or more first test pads on a first side of the first die and a first capping layer over each of the one or more first test pads. The method further includes contacting at least one first capping layer with one or more first test probes to perform a first test, identifying the first die as a known good die based on a result of the first test, and removing at least a portion of each first capping layer.

### TECHNICAL FIELD

The present disclosure relates generally to methods for microfabrication of integrated circuits, and, in particular embodiments, to methods for forming stacked semiconductor structures.

### BACKGROUND

Transistors per unit area on a chip have been increasing in density over the decades. As two-dimensional (2D) space available for circuit elements begins to exhaust available space, chip fabrication moves to three-dimensional (3D) designs in which transistors and other circuit elements are stacked on top of each other. Monolithic integration includes forming transistors on top of each other on a single wafer (substrate). Heterogeneous integration includes bonding two or more wafers and/or dies together to form vertically stacked devices.

### SUMMARY

In accordance with an embodiment of the present disclosure, a method includes forming a first die in a first wafer. The first die includes first bond pads and one or more first test pads on a first side of the first die and a first capping layer over each of the one or more first test pads. The method further includes contacting at least one first capping layer with one or more first test probes to perform a first test, identifying the first die as a known good die based on a result of the first test, and removing at least a portion of each first capping layer.

In accordance with another embodiment of the present disclosure, a method includes forming a first bonding layer on a first side of a first wafer. The first bonding layer includes a first dielectric layer and first bond pads embedded in the first dielectric layer. First capping layers are formed on the first bond pads. A hardness of the first capping layer is greater than a hardness of the first bond pads. A second bonding layer is formed on a first side of a second wafer. The second bonding layer includes a second dielectric layer and second bond pads embedded in the second dielectric layer. Second capping layers are formed on the second bond pads. A hardness of the second capping layer is greater than a hardness of the second bond pads. The first wafer is hybrid bonded to the second wafer.

In accordance with yet another embodiment of the present disclosure, a method includes providing a first substrate having a test pad, selectively depositing a capping layer over the test pad, and bonding the first substrate to a second substrate. The second substrate covers the test pad.

In accordance with yet another embodiment of the present disclosure, a method includes forming a first dielectric layer and first bond pads on a first substrate, forming a second dielectric layer and second bond pads on a second substrate, forming a ruthenium (Ru) capping layer over the first bond pads, the second bond pads, or both the first and second bond pads, and bonding the first substrate to the second substrate.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a cross-sectional view of a wafer in accordance with various embodiments;

FIGS. 2A-2C illustrate cross-sectional views of intermediate stages in the manufacturing of a wafer in accordance with various embodiments;

FIGS. 3A and 3B illustrate cross-sectional views of intermediate stages in the manufacturing of a wafer in accordance with various embodiments;

FIG. 4 illustrates a cross-sectional view of a wafer in accordance with various embodiments;

FIG. 5 illustrates a cross-sectional view of a wafer in accordance with various embodiments;

FIG. 6 illustrates a cross-sectional view of a stacked semiconductor structure in accordance with various embodiments;

FIG. 7 illustrates a cross-sectional view of a stacked semiconductor structure in accordance with various embodiments;

FIGS. 8A-8C illustrate cross-sectional views of intermediate stages in the manufacturing of a known good die in accordance with various embodiments;

FIGS. 9A and 9B illustrate cross-sectional views of intermediate stages in the manufacturing of a known good die in accordance with various embodiments;

FIGS. 10A and 10B illustrate cross-sectional views of intermediate stages in the manufacturing of a known good die in accordance with various embodiments;

FIGS. 11A-11C illustrate cross-sectional views of intermediate stages in the manufacturing of a stacked semiconductor structure in accordance with various embodiments;

FIG. 12 illustrates a cross-sectional view of a stacked semiconductor structure in accordance with various embodiments;

FIG. 13 illustrates a cross-sectional view of a stacked semiconductor structure in accordance with various embodiments;

FIG. 14 illustrates a flow diagram of a method for forming a known good die in accordance with various embodiments;

FIG. 15 illustrates a flow diagram of a method for forming a stacked semiconductor structure in accordance with various embodiments;

FIG. 16 illustrates a flow diagram of a method for forming a stacked semiconductor structure in accordance with various embodiments; and

FIG. 17 illustrates a flow diagram of a method for forming a stacked semiconductor structure in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

In one embodiment, a method for forming a known good die includes forming bond pads and test pads on a die, applying capping layers over the bond pads and the test pads, and forming native oxide layers on the capping layers. The die undergoes testing using probes that contact the native oxide layers over the test pads. Based on the test results, the die may be identified as a known good die. The method further involves removing the native oxide layers and at least a portion of each capping layer. A new native oxide layers may be formed on remaining capping layers.

In another embodiment, a wafer-to-wafer bonding process involves forming bonding layers on two separate wafers. Each bonding layer includes a dielectric layer with embedded bond pads. Capping layers are formed on the bond pads of both wafers. In some embodiments, native oxide layers are formed over on the capping layers of both wafers. In other embodiments, the formation of native oxide layers is omitted. The two wafers are then bonded together using a hybrid bonding technique.

In yet another embodiment, a die-to-wafer bonding process combines elements of the known good die formation and wafer bonding techniques. A first bonding layer is formed on a wafer. The first bonding layer comprises a first dielectric layer with embedded first bond pads. First capping layers are formed on the first bond pads. In some embodiments, first native oxide layers are formed on the first capping layers. In other embodiments, the formation of the first native oxide layers is omitted. A known good die is formed. A second bonding layer of the known good die comprises a second dielectric layer with embedded second bond pads and second capping layers on the second bond pads. In some embodiments, the second bonding layer further includes second native oxide layers on the second capping layers. In other embodiments, the second native oxide layers are omitted. The known good die is then hybrid bonded to the wafer.

Various embodiments of the present disclosure offer several advantages. The use of capping layers, particularly those made of materials like Ruthenium that form conductive native oxides, provides protection for the bond pads while maintaining electrical conductivity. This allows for reliable testing of dies without damaging the bond pads. The ability to selectively remove portions of the capping layers offers flexibility in the bonding process. Furthermore, the integration of known good die testing with wafer bonding processes can lead to improved yield and reliability in the stacked semiconductor structures.

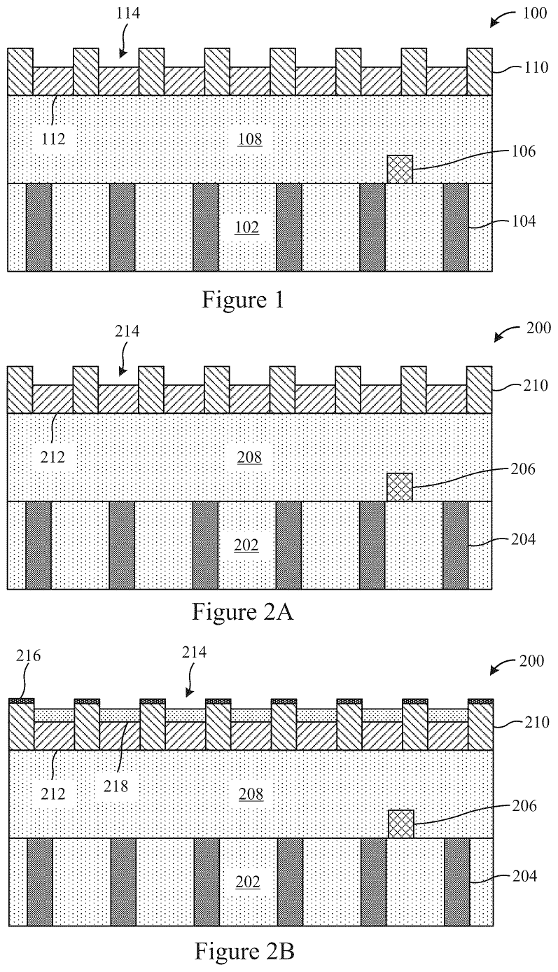

FIG. 1 illustrates a cross-sectional view of a wafer 100 in accordance with various embodiments. In various embodiments, the wafer 100 includes a substrate 102. The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate. In some embodiments, the substrate 102 may further comprise a plurality of device regions. In such embodiments, the substrate 102 may include isolation regions such as shallow trench isolation (STI) regions, diffusion regions, as well as other regions formed therein.

In some embodiments, through-silicon vias (TSVs) 104 are formed in the substrate 102 and extend vertically through the substrate 102. The TSVs 104 may comprises a conductive material and a dielectric liner isolating the conductive material from the substrate 102. The conductive material may comprise a suitable metallic material such as copper (Cu), for example. The dielectric liner may comprise a suitable dielectric material such as silicon oxide, silicon nitride, a combination thereof, or the like.

In some embodiments, active and/or passive devices 106 are formed on or within the substrate 102. The active and/or passive devices 106 may include transistors, diodes, inductors, capacitors, resistors, or the like. The active and/or passive devices 106 may be formed using any suitable manufacturing methods.

In some embodiments, an interconnect structure 108 is formed above the active and/or passive devices 106. In one or more embodiments, the interconnect structure 108 may comprise one or more dielectric layers and one or more metallization layers within the one or more dielectric layers, facilitating electrical connections between various components of the wafer 100. In some embodiments, the one or more dielectric layers may comprise one or more suitable dielectric materials such as silicon oxide, low-k dielectric materials, or the like. The one or more metallization layers may comprise a plurality of conductive lines and a plurality of conductive vias electrically coupling adjacent metallization layers. The metallization layers may comprise a suitable conductive material such as copper (Cu), for example. The metallization layers may be formed by a damascene process, a dual damascene process, or the like.

In some embodiments, a dielectric layer 110 is disposed on of the interconnect structure 108. In an embodiment, the dielectric layer 110 may comprise as silicon oxide, low-k dielectrics, or other suitable insulating materials. Bond pads 112 may be formed within the dielectric layer 110. In various embodiments, the bond pads 112 may be composed of copper, aluminum, or other conductive materials compatible with semiconductor manufacturing processes. The bond pads 112 may be configured to electrically and mechanically couple external semiconductor components (e.g., a wafer, die, or then like) to the wafer 100.

In some embodiments, the recesses 114 may be formed in the dielectric layer 110 exposing the bond pads 112. In one or more embodiments, the recesses 114 may be formed as a result of a chemical mechanical polishing (CMP) process, such as dishing. The recesses 114 may be further extended by a suitable etching process until a desired depth is achieved. The desired depth of the recesses 114 may be determined based on the thermal expansion coefficients of various materials used in the wafer 100 and any subsequent structures to be bonded to the wafer 100. This may allow for the formation of improved bonds in subsequent bonding processes.

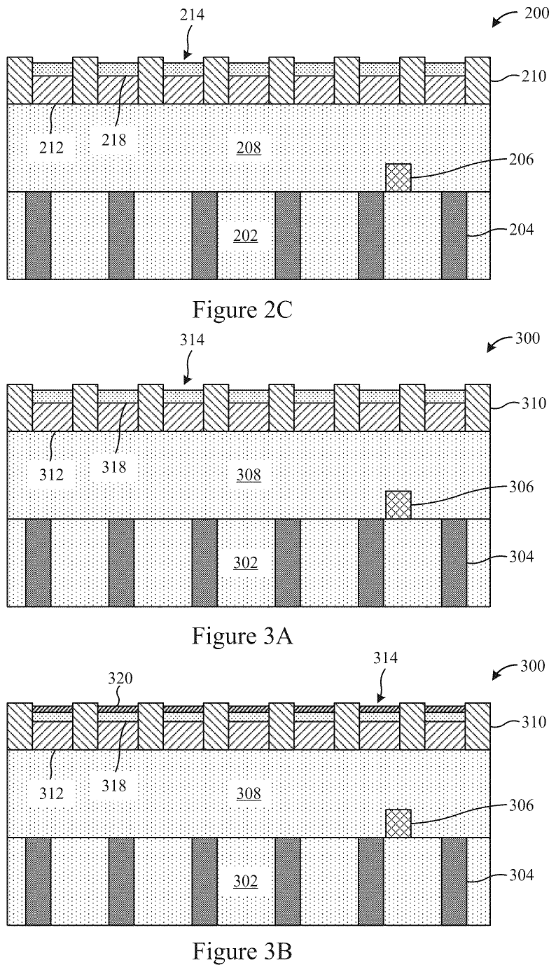

FIGS. 2A-2C illustrate cross-sectional views of intermediate stages in the manufacturing of a wafer 200 in accordance with various embodiments. Unless otherwise indicated, features denoted by reference numerals 2xx are similar to the corresponding features 1xx described in FIG. 1, and descriptions of the similar features are not repeated herein.

FIG. 2A shows a cross-sectional view of the wafer 200. The wafer 200 includes a substrate 202, TSVs 204, active and/or passive devices 206, an interconnect structure 208, a dielectric layer 210, and bond pads 212. In some embodiments, the recesses 214 may be formed in the dielectric layer 210 exposing the bond pads 212. In one or more embodiments, the recesses 214 may be formed as a result of a CMP process, such as dishing. The recesses 214 may be further extended by a suitable etching process until a desired depth is achieved. The desired depth of the recesses 214 may be determined based on the thermal expansion coefficients of various materials used in the wafer 200 and any subsequent structures to be bonded to the wafer 200. This may allow for the formation of improved bonds in subsequent bonding processes.

In FIG. 2B, a deposition inhibitor layer 216 is formed on the surface of the dielectric layer 210. The deposition inhibitor layer 216 may be configured to protect the dielectric layer 210 from the deposition of a capping layer material during the subsequent capping layer formation process. In some embodiment, the deposition inhibitor layer 216 may comprise self-assembled monolayers (SAMs), polymers, or other materials that selectively inhibit deposition on dielectric surfaces.

In some embodiments, capping layers 218 may be selectively formed on the bond pads 212. The selective formation of the capping layers 218 may be achieved due to the presence of the deposition inhibitor layer 216, which may reduce or prevent the capping layer material from depositing on the dielectric layer 210. In some embodiments, the material of the capping layers 218 may be selected such that a hardness of the capping layers 218 is greater than a hardness of the bond pads 212. In various embodiments, the capping layers 218 may comprise conductive materials that form conductive native oxides, such as ruthenium, iridium, or other suitable metals. In some embodiments, the capping layers 218 may be formed by chemical vapor deposition (CVD), atomic layer deposition (ALD), a combination thereof, or the like. The capping layers 218 may help to protect the bond pads 212 from oxidation and contamination while maintaining their electrical conductivity. In some embodiments, the capping layers 218 partially fill the recesses 214.

In FIG. 2C, the deposition inhibitor layer 216 may be removed, leaving the capping layers 218 selectively deposited on the bond pads 212. In some embodiments, the removal of the deposition inhibitor layer 216 may be accomplished through various methods such as ashing, wet etching, dry etching, or other suitable removal processes that do not substantially etch the capping layers 218 and/or the dielectric layer 210. A combined layer comprising the dielectric layer 210, the bond pads 212, and the capping layers 218 may be also referred to as a bonding layer.

The configuration of the wafer 200 illustrated in FIG. 2C may prepare the wafer 200 for subsequent processing steps, such as probing, testing, or bonding operations. The selective capping of the bond pads 212 using the capping layers 218 may help to maintain the integrity of the bond pad surfaces while allowing for good electrical and mechanical contacts in subsequent processes.

FIGS. 3A and 3B illustrate cross-sectional views of intermediate stages in the manufacturing of a wafer 300 in accordance with various embodiments. Unless otherwise indicated, features denoted by reference numerals 3xx are similar to the corresponding features 2xx described in the FIGS. 2A-2C, and descriptions of the similar features are not repeated herein.

FIG. 3A shows a cross-sectional view of the wafer 300. The wafer 300 includes a substrate 302, TSVs 304, active and/or passive devices 306, an interconnect structure 308, a dielectric layer 310, bond pads 312, and capping layers 318. In some embodiments, the structure of FIG. 3A may be formed using methods that are similar to the methods used to form the structure of FIG. 2C, and the description is not repeated herein.

In FIG. 3B, native oxide layers 320 are formed on the exposed surfaces of the capping layers 318. In some embodiments, the native oxide layers 320 may be formed naturally when the capping layers 318 are exposed to an oxygen-containing environment, such as air. In such embodiments, the formation of the native oxide layers 320 occurs without performing additional processing steps. The capping layers 318 with native oxide layers 320 formed thereon may be also referred to as combined capping layers.

In some embodiments, the capping layers 318 comprise conductive materials such that the native oxide layers 320 are conductive. In an embodiment, when the capping layers 318 comprises ruthenium, the native oxide layers 320 comprise ruthenium dioxide (RuO₂), which is a conductive oxide. In another embodiment, when the capping layers 318 comprises iridium, the native oxide layers 320 comprise iridium dioxide (IrO₂), which is a conductive oxide.

The native oxide layers 320 may provide several advantages. The native oxide layers 320 may protect the underlying bond pads 312 from further oxidation or contamination. In various embodiments, the conductive native oxide layers 320 may allow for testing of the wafer 300 without the need to break through an insulating oxide layer, which may lead to more reliable test results and reduced damage to the bond pad surfaces. The conductive native oxide layers 320 may participate in subsequent bonding processes, potentially improving the quality and reliability of the bonds formed.

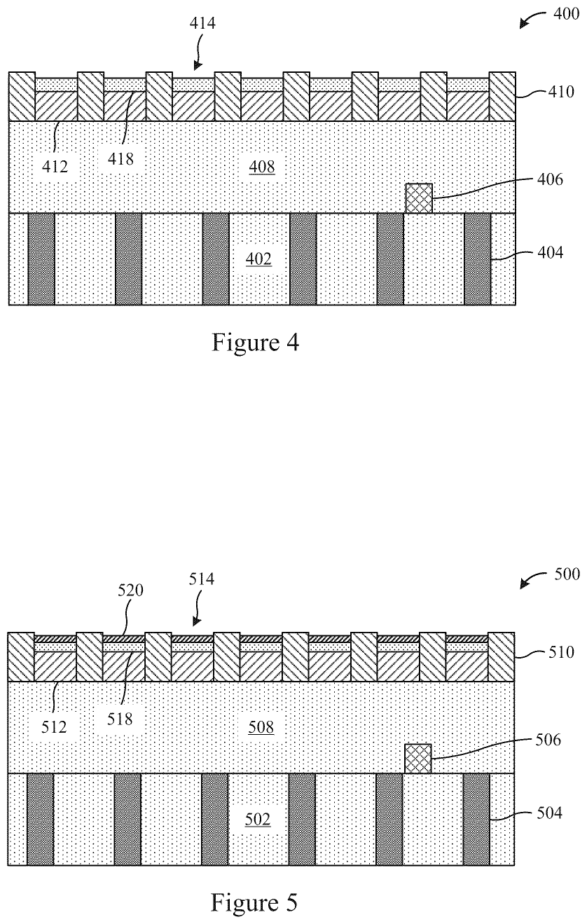

FIG. 4 illustrates a cross-sectional view of a wafer 400 in accordance with various embodiments. Unless otherwise indicated, features denoted by reference numerals 4xx are similar to the corresponding features 2xx described in the FIG. 2A-2C, and descriptions of the similar features are not repeated herein. The wafer 400 includes a substrate 402, TSVs 404, active and/or passive devices 406, an interconnect structure 408, a dielectric layer 410, bond pads 412, and capping layers 418. In some embodiments, the structure of FIG. 4 may be formed using methods that are similar to the methods used to form the structure of FIG. 2C, and the description is not repeated herein. As described below in greater detail, the wafer 400 may be bonded to the wafer 200 (see FIG. 2C) to form a stacked semiconductor structure. A combined layer comprising the dielectric layer 410, the bond pads 412, and the capping layers 418 may be also referred to as a bonding layer.

FIG. 5 illustrates a cross-sectional view of a wafer 500 in accordance with various embodiments. Unless otherwise indicated, features denoted by reference numerals 5xx are similar to the corresponding features 3xx described in the previous FIGS. 3A and 3B, and descriptions of the similar features are not repeated herein. The wafer 500 includes a substrate 502, TSVs 504, active and/or passive devices 506, an interconnect structure 508, a dielectric layer 510, bond pads 512, capping layers 518, and native oxide layers 520. In some embodiments, the structure of FIG. 5 may be formed using methods that are similar to the methods used to form the structure of FIG. 3B, and the description is not repeated herein. As described below in greater detail, the wafer 500 may be bonded to the wafer 300 (see FIG. 3B) to form a stacked semiconductor structure. A combined layer comprising the dielectric layer 510, the bond pads 512, the capping layers 518, and the native oxide layers 520 may be also referred to as a bonding layer. The capping layers 518 with native oxide layers 520 formed thereon may be also referred to as combined capping layers.

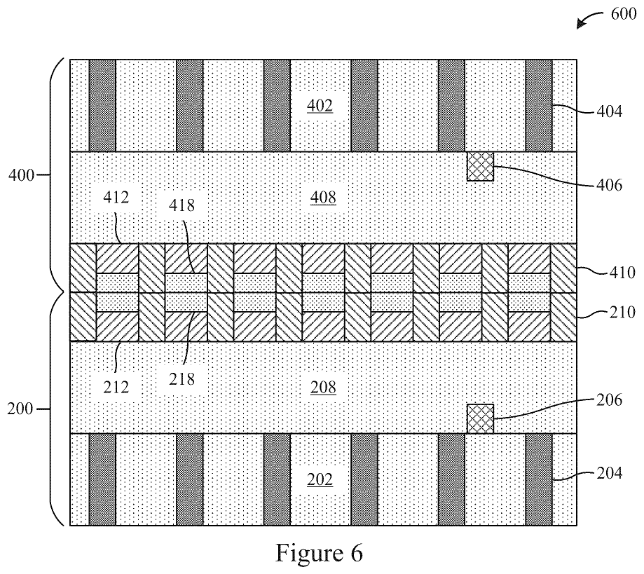

FIG. 6 illustrates a cross-sectional view of a stacked semiconductor structure 600 in accordance with various embodiments. In some embodiments, the wafer 400 (see FIG. 4) is bonded to the wafer 200 (see FIG. 2C) to form the stacked semiconductor structure 600. In an embodiment, the wafer 200 may be a logic wafer and may comprise logic circuitry, and the wafer 400 may be a memory wafer and may comprise memory circuitry.

In some embodiments, the bonding process used to create the stacked semiconductor structure 600 may be a hybrid bonding process. This process creates both mechanical and electrical connections between the wafers 200 and 400. The hybrid bonding process may include cleaning bonded surfaces of the wafers 200 and 400, aligning the wafers 200 and 400 such that the bond pads 212 of the wafer 200 is aligned with the bond pads 412 of the wafer 400, bringing the bonding surfaces of the wafers 200 and 400 into contact to form a bond between the dielectric layers 210 and 410, performing a thermal anneal to strengthen the bond between the dielectric layers 210 and 410 and form a bond between the capping layers 218 and 418. In some embodiments, the materials of the capping layers 218 and 418 may diffuse into each other to form the bond between the capping layers 218 and 418.

In some embodiments, the capping layers 218 and 418 may protect their respective bond pads 212 and 412 from oxidation and contamination throughout the bonding process. In various embodiments, the conductive nature of the capping layers 218 and 418 allows for electrical connectivity between the bond pads 212 and 412 of the wafers 200 and 400, even if native oxides are formed on the surfaces of the capping layers 218 and 418.

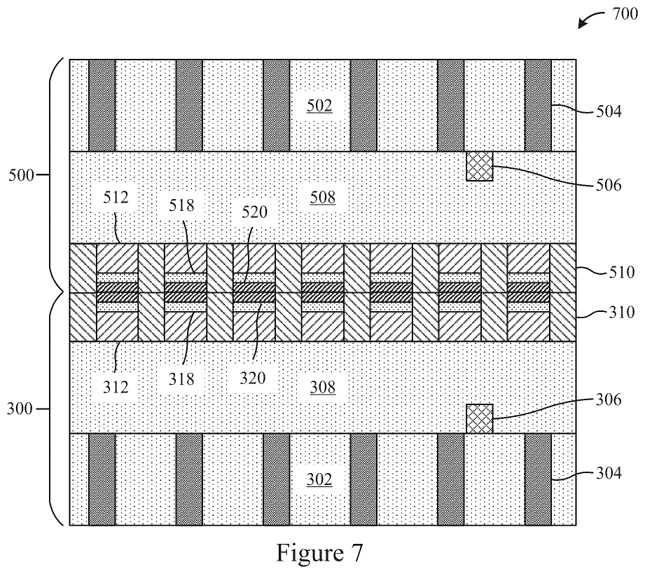

FIG. 7 illustrates a cross-sectional view of a stacked semiconductor structure 700 in accordance with various embodiments. In some embodiments, the wafer 500 (see FIG. 5) is bonded to the wafer 300 (see FIG. 3B) to form the stacked semiconductor structure 700. In an embodiment, the wafer 300 may be a logic wafer and may comprise logic circuitry, and the wafer 500 may be a memory wafer and may comprise memory circuitry.

In some embodiments, the bonding process used to create the stacked semiconductor structure 700 may be a hybrid bonding process. This process creates both mechanical and electrical connections between the wafers 300 and 500. The hybrid bonding process may include cleaning bonded surfaces of the wafers 300 and 500, aligning the wafers 300 and 500 such that the bond pads 312 of the wafer 300 is aligned with the bond pads 512 of the wafer 500, bringing the bonding surfaces of the wafers 300 and 500 into contact to form a bond between the dielectric layers 310 and 510, performing a thermal anneal to strengthen the bond between the dielectric layers 310 and 510 and form a bond between the native oxide layers 320 and 520. In some embodiments, the materials of the native oxide layers 320 and 520 may diffuse into each other to form the bond between the native oxide layers 320 and 520.

In some embodiments, the native oxide layers 320 and 520 may protect their respective bond pads 312 and 512 from oxidation and contamination throughout the bonding process. In various embodiments, when the native oxide layers 320 and 520 are conductive layers, the conductive nature of the native oxide layers 320 and 520 allows for electrical connectivity between the bond pads 312 and 512 of the wafers 300 and 500.

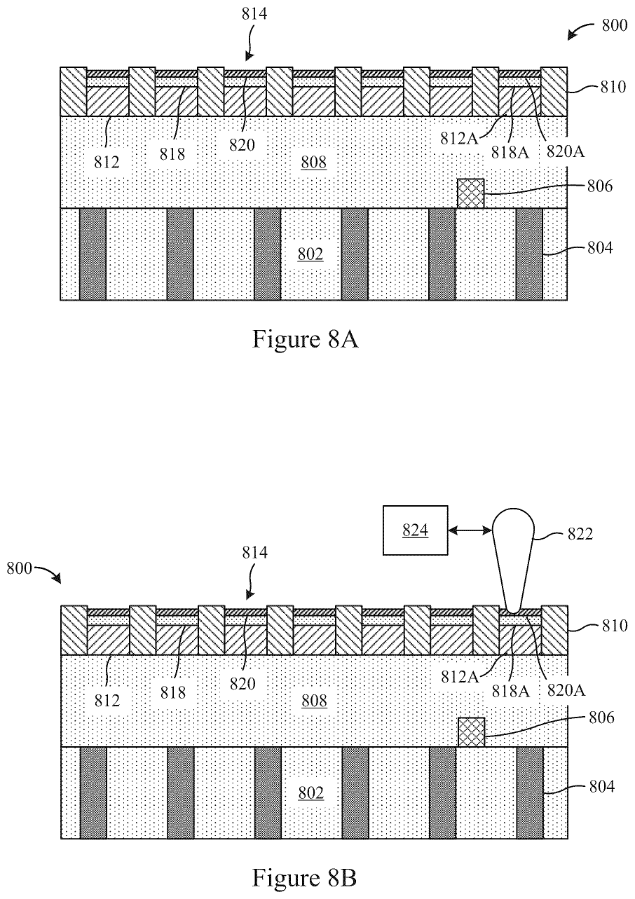

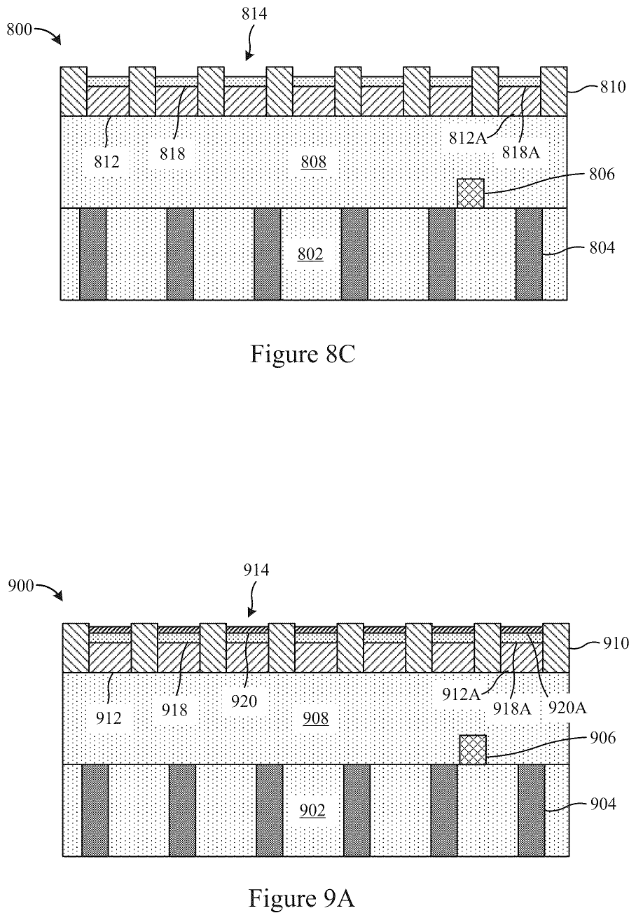

FIGS. 8A-8C illustrate cross-sectional views of intermediate stages in the manufacturing of a known good die 800 in accordance with various embodiments. Unless otherwise indicated, features denoted by reference numerals 8xx are similar to the corresponding features 3xx described in FIGS. 3A and 3B, and descriptions of the similar features are not repeated herein.

FIG. 8A shows a cross-sectional view of the die 800. The die 800 includes a substrate 802, TSVs 804, active and/or passive devices 806, an interconnect structure 908, a dielectric layer 810, bond pads 812, capping layers 818, native oxide layers 820. The capping layers 818 with native oxide layers 820 formed thereon may be also referred to as combined capping layers. In some embodiments, one or more of the bond pads 812 (e.g., bond pad 812A) may be configured to act as a test pad and may be referred to as a test pad. The test pad may be used during a test process to determine whether the die 800 is a known good die.

In various embodiments, the die 800 may be formed as part of a larger wafer which is subsequently singulated to form individual dies. The wafer-level processing allows for efficient manufacturing of multiple dies simultaneously. The singulation process can occur at various stages of the overall manufacturing process, depending on the specific requirements of the final device and the chosen manufacturing flow. In one embodiment, the dies of the wafer are tested before performing the singulation process. In another embodiment, the dies of the wafer are tested after performing the singulation process. In some embodiments, the wafer may be formed using methods that are similar to the methods used to form the wafer 300 (see FIGS. 3A and 3B), and the description is not repeated herein.

In FIG. 8B, a testing process is performed on the die 800 to determine whether the die 800 is a known good die. In some embodiments, a probe 822 of a tester 824 is brought into contact with the native oxide layer 820A formed on the test pad 812A. In an embodiment, the probe 822 may make multiple contacts with the native oxide layer 820A during the testing process. The conductive nature of the native oxide layer 820A allows for electrical testing without the need to break through the native oxide layer 820A, reducing damage to the underlying test pad 812A. When the die 800 is still part of a wafer at this stage, this testing process may be performed on multiple dies simultaneously or sequentially before singulation. In an embodiment, the probe 822 may partially extend into the native oxide layer 820A and form a divot in the native oxide layer 820A. In another embodiment, the probe 822 may extend through the native oxide layer 820A and partially into the capping layer 818A formed on the test pad 812A.

In some embodiments, the testing process may determine that the die 800 is a known good die. In such embodiments, additional process steps (e.g., bonding process) may be performed on the die 800. In other embodiments, the testing process may determine that the die 800 is a faulty die. In such embodiments, the die 800 may be reworked, used a dummy die, or discarded.

FIG. 8C shows the die 800 after performing the test process. In some embodiments, when the probe 822 partially extends into the native oxide layer 820A, the native oxide layers 820 and 820A may be removed to expose the capping layers 818 and 818A. The native oxide layers 820 and 820A may be removed by a suitable etch process, such as a wet atomic layer etch (ALE) process.

In other embodiments, when the probe 822 (see FIG. 8B) extends through the native oxide layer 820A and partially into the capping layer 818A formed on the test pad 812A, the native oxide layers 820 and 820A may be removed to expose the capping layers 818 and 818A followed by the partial removal of the capping layers 818 and 818A to planarize the capping layers 818 and 818A. The native oxide layers 820 and 820A may be removed by a first suitable etch process, such as a wet atomic layer etch (ALE) process. The capping layers 818 and 818A may be planarized to remove any divots formed by the probe 822 (see FIG. 8B) using a second suitable etch process, such as a wet ALE process. By using the wet ALE process, a speed of the planarization process may be increased compared to CMP.

The use of capping layers 818, 818A and native oxide layers 820, 820A provides protection for the bond pads 812 and test pad 812A during the manufacturing and testing processes. The conductive nature of the native oxide layers 820 and 820A allows for effective electrical testing without causing significant damage to the test pads 812A. A combined layer comprising the dielectric layer 810, the bond pads 812, the test pad 812A, and the capping layers 818 and 818A may be also referred to as a bonding layer.

In various embodiments, this process may be used to identify known good dies before bonding, which may improve the yield and reliability of the final stacked semiconductor structures. The ability to perform accurate testing while minimizing damage to the test pads may lead to more robust and reliable connections in the final stacked semiconductor structures. When applied at the wafer level, this process may offer significant efficiency in manufacturing and testing multiple dies simultaneously.

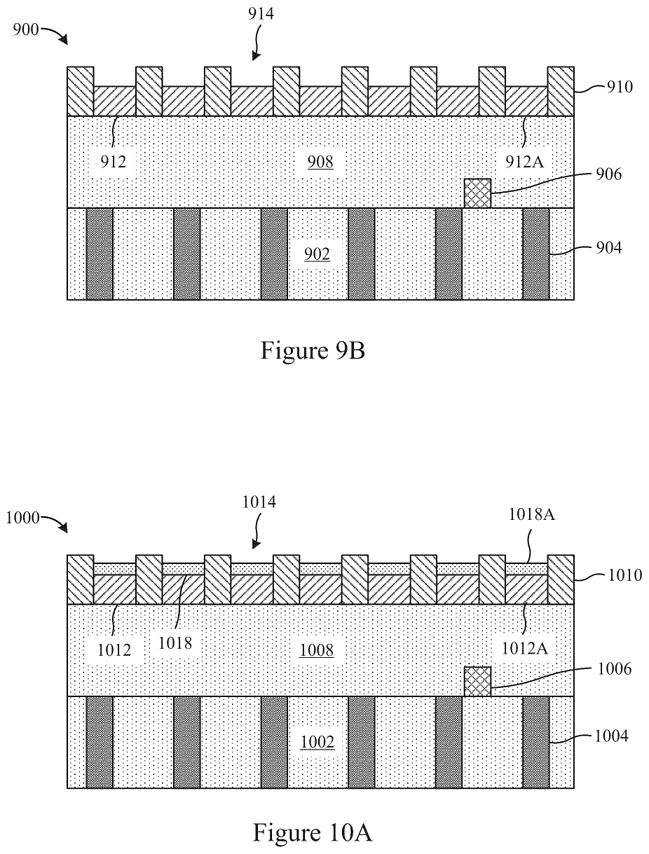

FIGS. 9A and 9B illustrate cross-sectional views of intermediate stages in the manufacturing of a known good die 900 in accordance with various embodiments. Unless otherwise indicated, features denoted by reference numerals 9xx are similar to the corresponding features 8xx described in FIGS. 8A and 8B, and descriptions of the similar features are not repeated herein.

FIG. 9A shows a cross-sectional view of the die 900. In some embodiments, the die 900 may be formed using methods that are similar to the methods for forming the die 800 of FIG. 8A, and the description is not repeated herein. In some embodiments, a testing process is performed in the die 900 to determine whether the die 900 is a known good die. In one embodiment, the testing process may be performed as described above with reference to FIG. 8B, and the description is not repeated herein.

In some embodiments, the testing process may determine that the die 900 is a known good die. In such embodiments, additional process steps (e.g., bonding process) may be performed on the die 900. In other embodiments, the testing process may determine that the die 800 is a faulty die. In such embodiments, the die 900 may be reworked, used a dummy die, or discarded.

FIG. 9B shows the die 900 after performing the test process. In some embodiments, the native oxide layers 920 and 920A (see FIG. 9A) and the capping layers 918 and 918A may be removed to expose the bond pads 912 and the test pad 912A. The native oxide layers 920 and 920A may be removed by a first suitable etch process, such as a wet atomic layer etch (ALE) process. The capping layers 918 and 918A may be removed by a second suitable etch process, such as a wet ALE process.

The use of capping layers 918, 918A (see FIG. 9A) and native oxide layers 920, 920A (see FIG. 9A) provides protection for the bond pads 912 and test pad 912A during the manufacturing and testing processes. The conductive nature of the native oxide layers 920 and 920A allows for effective electrical testing without causing significant damage to the test pads 912A. A combined layer comprising the dielectric layer 910, the bond pads 912, and the test pad 912A may be also referred to as a bonding layer.

In various embodiments, this process may be used to identify known good dies before bonding, which may improve the yield and reliability of the final stacked semiconductor structures. The ability to perform accurate testing while minimizing damage to the test pads may lead to more robust and reliable connections in the final stacked semiconductor structures. When applied at the wafer level, this process may offer significant efficiency in manufacturing and testing multiple dies simultaneously.

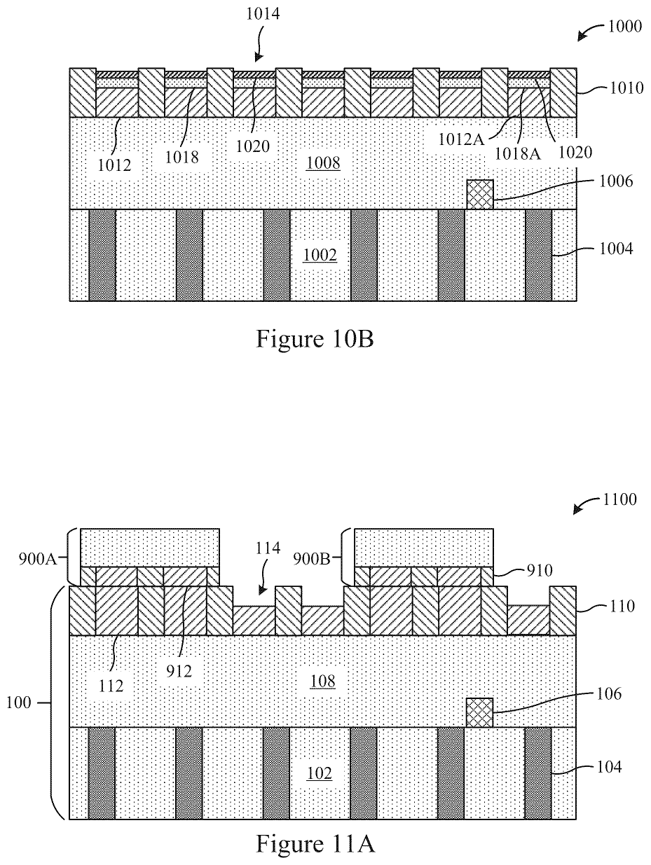

FIGS. 10A and 10B illustrate cross-sectional views of intermediate stages in the manufacturing of a known good die 1000 in accordance with various embodiments. Unless otherwise indicated, features denoted by reference numerals 10xx are similar to the corresponding features 8xx described in FIGS. 8A and 8B, and descriptions of the similar features are not repeated herein.

FIG. 10A shows a cross-sectional view of the die 1000. In some embodiments, the die 1000 may be formed using methods that are similar to the methods for forming the die 800 of FIG. 8C, and the description is not repeated herein.

In FIG. 10B, native oxide layers 1020 are formed over the capping layers 1018 and 1018A. In some embodiments, the native oxide layers 1020 may be formed naturally when the capping layers 1018 and 1018A are exposed to an oxygen-containing environment, such as air. In such embodiments, the formation of the native oxide layers 1920 occurs without performing additional processing steps.

In some embodiments, the capping layers 1018 and 1018A comprise conductive materials such that the native oxide layers 1020 are conductive. In an embodiment, when the capping layers 1018 and 1018A comprises ruthenium, the native oxide layers 1020 comprise ruthenium dioxide (RuO₂), which is a conductive oxide. In another embodiment, when the capping layers 1018 and 1018A comprises iridium, the native oxide layers 1020 comprise iridium dioxide (IrO₂), which is a conductive oxide. The capping layers 1018 with native oxide layers 1020 formed thereon may be also referred to as combined capping layers.

The native oxide layers 1020 may provide several advantages. The native oxide layers 1020 may protect the underlying bond pads 1012 and test pad 1012A from further oxidation or contamination. The conductive native oxide layers 1020 may participate in subsequent bonding processes, potentially improving the quality and reliability of the bonds formed. A combined layer comprising the dielectric layer 1010, the bond pads 1012, the test pad 1012A, the capping layers 1018 and 1018A, and the native oxide layers 1020 may be also referred to as a bonding layer.

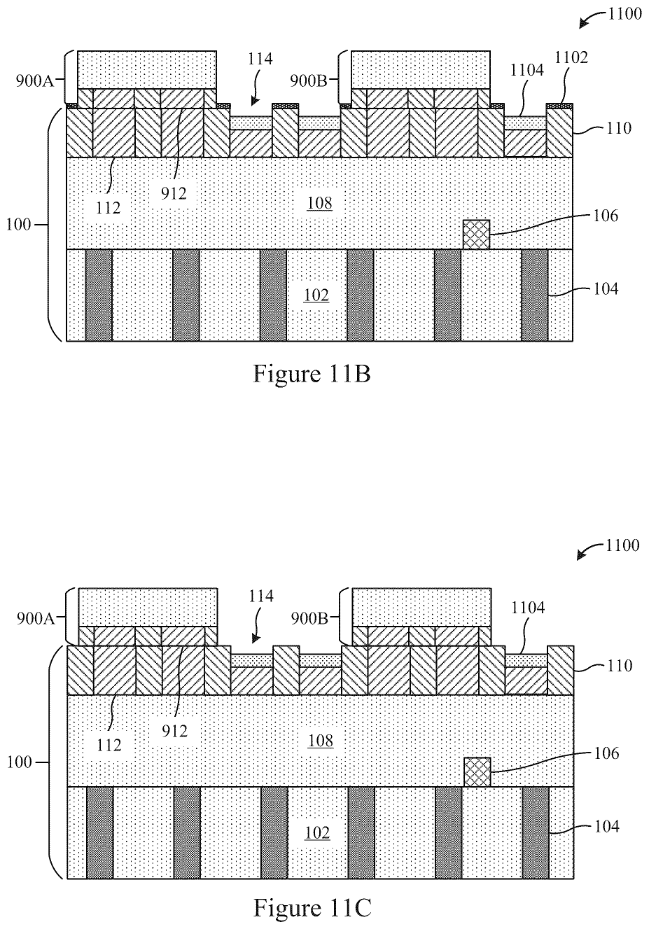

FIGS. 11A-11C illustrate cross-sectional views of intermediate stages in the manufacturing of a stacked semiconductor structure 1100 in accordance with various embodiments. In FIG. 11A, dies 900 (see FIG. 9B), such as the dies 900A and 900B are bonded to the wafer 100. The bonding of the dies 900A and 900B to the wafer 100 may have been achieved through a hybrid bonding process, creating both electrical and mechanical connections between the dies 900A and 900B and the wafer 100. The hybrid bonding process may include cleaning bonded surfaces of the wafer 100 and the dies 900A and 900B, aligning the wafer 100 and the dies 900A and 900B such that the bond pads 112 of the wafer 100 is aligned with the bond pads 912 of the dies 900A and 900B, bringing the bonding surfaces of the wafer 100 and the dies 900A and 900B into contact to form a bond between the dielectric layers 110 and 910, performing a thermal anneal to strengthen the bond between the dielectric layers 110 and 910 and form a bond between the bond pads 112 and 912. In some embodiments, the materials of the bond pads 112 and 912 may diffuse into each other to form the bond between the bond pads 112 and 912.

In FIG. 11B, a deposition inhibitor layer 1102 is formed on the surface of the dielectric layer 110 of the wafer 100. The deposition inhibitor layer 1102 may be configured to protect the dielectric layer 110 from the deposition of a capping layer material during the subsequent capping layer formation process. In some embodiment, the deposition inhibitor layer 1102 may comprise self-assembled monolayers (SAMs), polymers, or other materials that selectively inhibit deposition on dielectric surfaces.

In some embodiments, capping layers 1104 may be selectively formed on the bond pads 112. The selective formation of the capping layers 1104 may be achieved due to the presence of the deposition inhibitor layer 1102, which may reduce or prevent the capping layer material from depositing on the dielectric layer 110. In various embodiments, the capping layers 1104 may comprise conductive materials that form conductive native oxides, such as ruthenium, iridium, or other suitable metals. The capping layers 1104 may help to protect the bond pads 112 from oxidation and contamination while maintaining their electrical conductivity. In some embodiments, the capping layers 1104 partially fill the recesses 114.

In FIG. 11C, the deposition inhibitor layer 1102 (see FIG. 11B) may be removed, leaving the capping layers 1104 selectively deposited on the bond pads 112. In some embodiments, the removal of the deposition inhibitor layer 1102 (see FIG. 11B) may be accomplished through various methods such as ashing, wet etching, dry etching, or other suitable removal processes that do not substantially etch the capping layers 1104 and/or the dielectric layer 110. The selective deposition of capping layers 1104 on the exposed bond pads 112 may protect the exposed bond pads 112 from oxidation or contamination, potentially improving long-term reliability. Additionally, if further processing or stacking is needed, the capping layers 1104 may serve as excellent interfaces for subsequent bonding or interconnection steps.

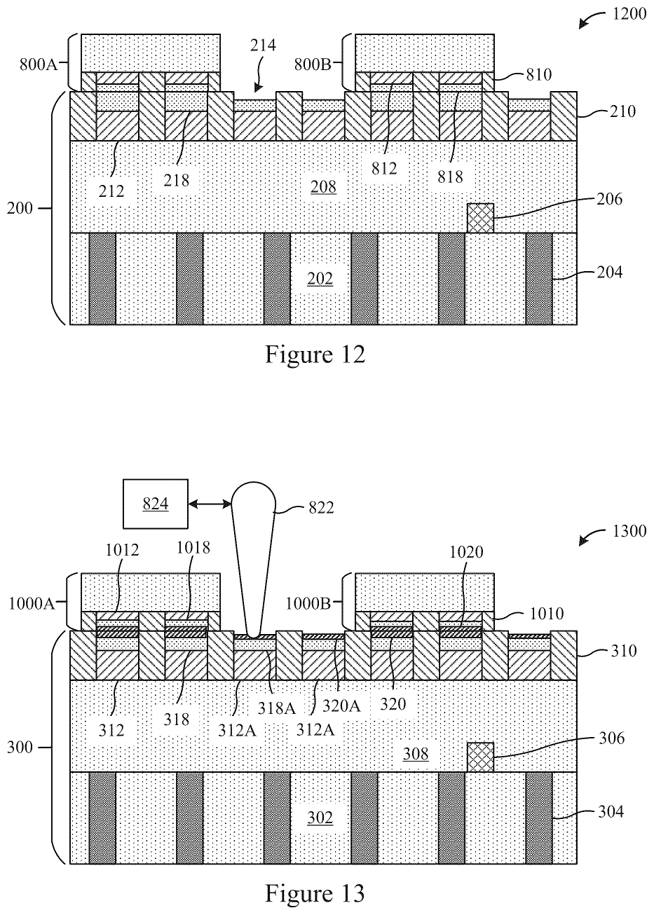

FIG. 12 illustrates a cross-sectional view of a stacked semiconductor structure 1200 in accordance with various embodiments. In some embodiments, dies 800 (see FIG. 8C), such as the dies 800A and 800B are bonded to the wafer 200. The bonding of the dies 800A and 800B to the wafer 200 may have been achieved through a hybrid bonding process, creating both electrical and mechanical connections between the dies 800A and 800B and the wafer 200. The hybrid bonding process may include cleaning bonded surfaces of the wafer 200 and the dies 800A and 800B, aligning the wafer 200 and the dies 800A and 800B such that the bond pads 212 of the wafer 200 is aligned with the bond pads 812 of the dies 800A and 800B, bringing the bonding surfaces of the wafer 200 and the dies 800A and 800B into contact to form a bond between the dielectric layers 210 and 810, performing a thermal anneal to strengthen the bond between the dielectric layers 210 and 810 and form a bond between the capping layers 218 and 818. In some embodiments, the materials of capping layers 218 and 818 may diffuse into each other to form the bond between the capping layers 218 and 818.

FIG. 13 illustrates a cross-sectional view of a stacked semiconductor structure 1300 in accordance with various embodiments. In some embodiments, dies 1000 (see FIG. 10B), such as the dies 1000A and 1000B are bonded to the wafer 300. The bonding of the dies 1000A and 1000B to the wafer 300 may have been achieved through a hybrid bonding process, creating both electrical and mechanical connections between the dies 1000A and 1000B and the wafer 300. The hybrid bonding process may include cleaning bonded surfaces of the wafer 300 and the dies 1000A and 1000B, aligning the wafer 300 and the dies 1000A and 1000B such that the bond pads 312 of the wafer 300 is aligned with the bond pads 1012 of the dies 1000A and 1000B, bringing the bonding surfaces of the wafer 300 and the dies 1000A and 1000B into contact to form a bond between the dielectric layers 310 and 1010, performing a thermal anneal to strengthen the bond between the dielectric layers 310 and 1010 and form a bond between the native oxide layers 320 and 1020. In some embodiments, the materials of the native oxide layers 320 and 1020 may diffuse into each other to form the bond between the native oxide layers 320 and 1020. In some embodiments, one or more of the bond pads 312 (e.g., bond pad 312A) that are formed in scribe lines of the wafer 300 may be configured to act as test pads and may be referred to as test pads.

In some embodiments, after bonding the die 1000A to the wafer 300, a testing process is performed on the stacked semiconductor structure 1300 to determine whether the bonding process provides a desired electrical and mechanical connections between the die 1000A to the wafer 300. In some embodiments, a probe 822 of a tester 824 is brought into contact with the native oxide layer 320A formed on the test pad 312A. In an embodiment, the probe 822 may make multiple contacts with the native oxide layer 320A during the testing process. The conductive nature of the native oxide layer 320A allows for electrical testing without the need to break through the native oxide layer 320A, reducing damage to the underlying test pad 312A. In an embodiment, the probe 822 may partially extend into the native oxide layer 320A and form a divot in the native oxide layer 320A. In another embodiment, the probe 822 may extend through the native oxide layer 320A and partially into the capping layer 318A formed on the test pad 312A. In some embodiments, the testing process may be repeated after each die is bonded to the wafer 300. In other embodiments, the testing process may be performed after all dies are bonded to the wafer 300.

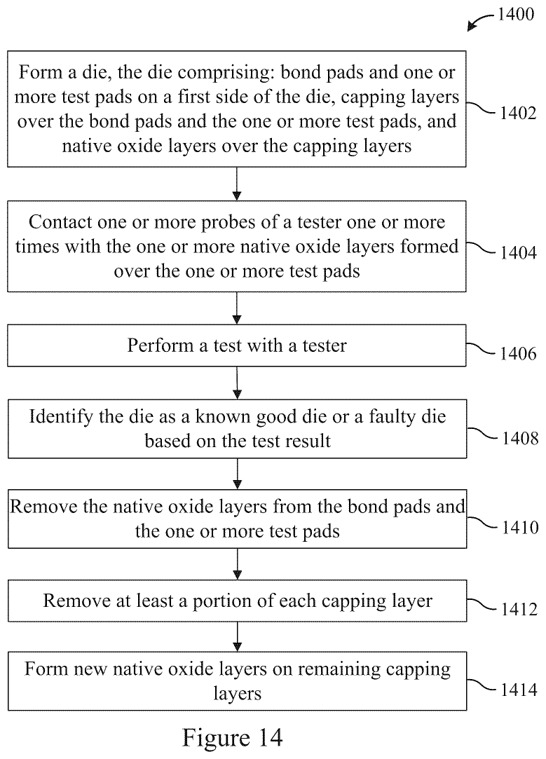

FIG. 14 illustrates a flow diagram of a method 1400 for forming a known good die in accordance with various embodiments. In step 1402, a die (e.g., die 800) is formed, as described above with reference to FIG. 8A. In some embodiments, the die (e.g., die 800) may comprise bond pads (e.g., bond pads 812) and one or more test pads (e.g., test pad 812A) on a first side of the die (e.g., die 800), capping layers (e.g., capping layers 818) over the bond pads (e.g., bond pads 812) and the one or more test pads (e.g., test pad 812A), and native oxide layers (e.g., native oxide layers 820) over the capping layers (e.g., capping layers 818), as described above with reference to FIG. 8A. In step 1404, one or more probes (e.g., probe 822) of a tester (e.g., tester 824) contact one or more times with the one or more native oxide layers (e.g., native oxide layers 820) formed over the one or more test pads (e.g., test pad 812A), as described above with reference to FIG. 8B. In step 1406, a test is performed with a tester (e.g., tester 824), as described above with reference to FIG. 8B.

In step 1408, the die (e.g., die 800) is identified as a known good die or a faulty die based on the test result. In step 1410, the (e.g., native oxide layers 820) are removed from the bond pads (e.g., bond pads 812) and the one or more test pads (e.g., test pad 812A). In step 1412, at least a portion of each capping layer 918 is removed. In various embodiments, each capping layer (e.g., capping layers 818) may be partially or fully removed in step 1412. In step 1414, new native oxide layers (e.g., native oxide layers 1020) are formed on remaining capping layers (e.g., capping layers 1018), as described above with reference to FIG. 10B. In one or more embodiments, step 1414 may be omitted if the capping layers (e.g., capping layers 818) are fully removed in step 1412.

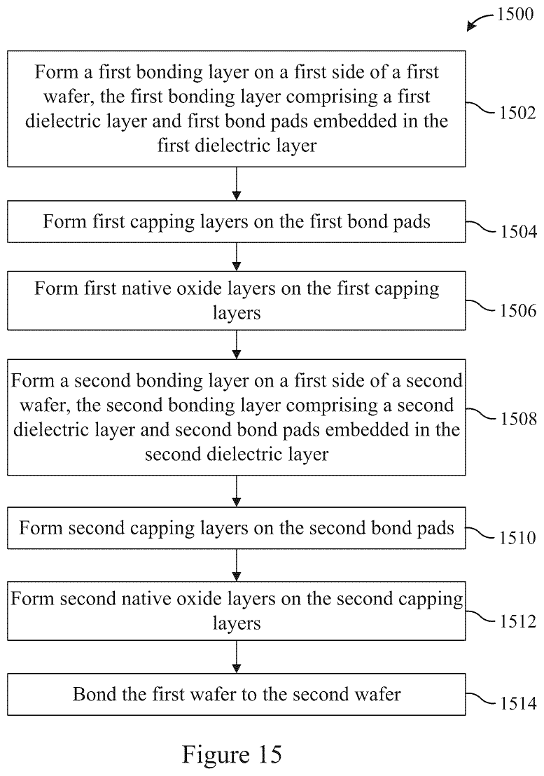

FIG. 15 illustrates a flow diagram of a method 1500 for forming a stacked semiconductor structure in accordance with various embodiments. In step 1502, a first bonding layer is formed on a first side of a first wafer (e.g., wafer 200 or 300), the first bonding layer comprising a first dielectric layer (e.g., dielectric layer 210 or 310) and first bond pads (e.g., bond pads 212 or 312) embedded in the first dielectric layer (e.g., dielectric layer 210 or 310), as described above with reference to FIG. 2A or 3A. In step 1504, first capping layers (e.g., capping layers 218 or 318) are formed on the first bond pads (e.g., bond pads 212 or 312), as described above with reference to FIG. 2B or 3A. In step 1506, first native oxide layers (e.g., native oxide layers 320) are formed on the first capping layers (e.g., capping layers 318), as described above with reference to FIG. 3B. In some embodiments, step 1506 may be omitted.

In step 1508, a second bonding layer is formed on a first side of a second wafer (e.g., wafer 400 or 500), the second bonding layer comprising a second dielectric layer (e.g., dielectric layer 410 or 510) and second bond pads (e.g., bond pads 412 or 512) embedded in the second dielectric layer (e.g., dielectric layer 410 or 510), as described above with reference to FIG. 4 or 5. In step 1510, second capping layers (e.g., capping layers 418 or 518) are formed on the second bond pads (e.g., bond pads 412 or 512), as described above with reference to FIG. 4 or 5. In step 1512, second native oxide layers (e.g., native oxide layers 520) are formed on the second capping layers (e.g., capping layers 518), as described above with reference to FIG. 5. In some embodiments, step 1512 may be omitted. In step 1514, the first wafer (e.g., wafer 200 or 300) is bonded to the second wafer (e.g., wafer 400 or 500), forming a stacked semiconductor structure (e.g., stacked semiconductor structure 600 or 700), as described above with reference to FIG. 6 or 7.

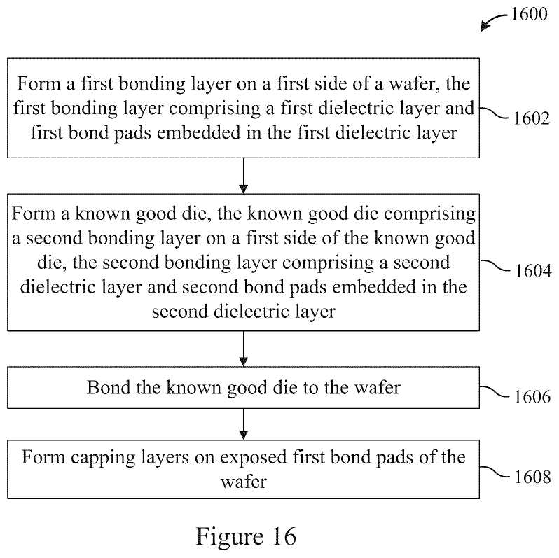

FIG. 16 illustrates a flow diagram of a method 1600 for forming a stacked semiconductor structure in accordance with various embodiments. In step 1602, a first bonding layer is formed on a first side of a wafer (e.g., wafer 100), the first bonding layer comprising a first dielectric layer (e.g., dielectric layer 110) and first bond pads (e.g., bond pads 112) embedded in the first dielectric layer (e.g., dielectric layer 110), as described above with reference to FIG. 11A.

In step 1604, a known good die (e.g., die 900A) is formed, as described above with reference to FIGS. 9A and 9B. The formation of the known good die (e.g., die 900A) involves creating a second bonding layer on a first side of the known good die (e.g., die 900A), where the second bonding layer comprises a second dielectric layer (e.g., dielectric layer 910) and second bond pads (e.g., bond pads 912) embedded in the second dielectric layer (e.g., dielectric layer 910), as described above with reference to FIG. 11B. In various embodiments, the formation of the known good die (e.g., die 900A) may follow the method 1400 described in FIG. 14.

In step 1606, the known good die (e.g., die 900A) is bonded to the wafer (e.g., wafer 100), as described above with reference to FIG. 11A. In step 1608, capping layers (e.g., capping layers 1104) are formed on exposed first bond pads (e.g., bond pads 112) of the wafer (e.g., wafer 100), as described above with reference to FIGS. 11B and 11C.

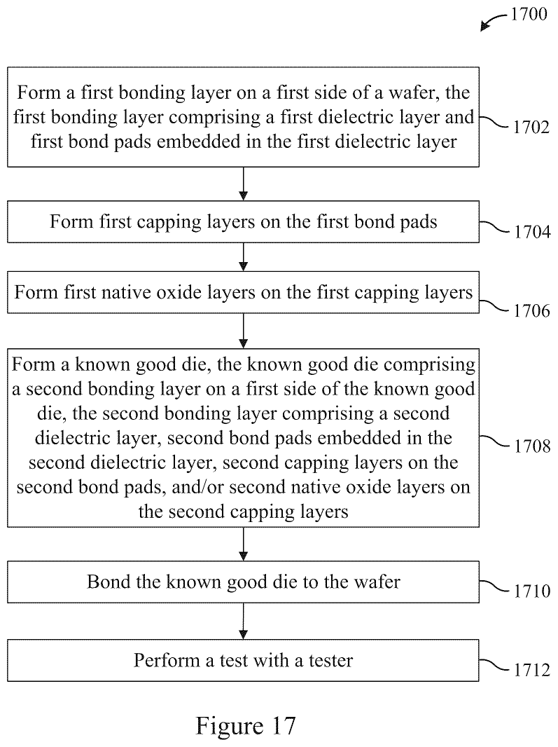

FIG. 17 illustrates a flow diagram of a method 1700 for forming a stacked semiconductor structure in accordance with various embodiments. In step 1702, a first bonding layer is formed on a first side of a wafer (e.g., wafer 200 or 300), where the first bonding layer comprises a first dielectric layer (e.g., dielectric layer 210 or 310) and first bond pads (e.g., bond pads 212 or 312) embedded in the first dielectric layer (e.g., dielectric layer 210 or 310), as described above with reference to FIG. 2A or 3A. In step 1704, first capping layers (e.g., capping layers 218 or 318) are formed on the first bond pads (e.g., bond pads 212 or 312), as described above with reference to FIGS. 2A and 2B, or 3A. In step 1706, first native oxide layers (e.g., native oxide layers 320) are formed on the first capping layers (e.g., capping layers 318), as described above with reference to FIG. 3B. In some embodiments, step 1706 may be omitted.

In step 1708, a known good die (e.g., die 800 or 1000) is formed. The formation of the known good die (e.g., die 800 or 1000) involves creating a second bonding layer on a first side of the known good die (e.g., die 800 or 1000), where the second bonding layer comprises a second dielectric layer (e.g., dielectric layer 810 or 1010), second bond pads (e.g., bond pads 812 or 1012) embedded in the second dielectric layer (e.g., dielectric layer 810 or 1010) and second capping layers (e.g., capping layers 818 or 1018) are formed on the second bond pads (e.g., bond pads 812 or 1012), as described above with reference to FIG. 8A or 10A.

In some embodiments, the second native oxide layers (e.g., native oxide layers 1020) may be formed on the second capping layers (e.g., capping layers 1018), as described above with reference to FIG. 10B. In other embodiments, the formation of native oxide layers may be omitted, as described above with reference to FIG. 8C. In various embodiments, the formation of the known good die (e.g., die 800 or 1000) may follow the method 1400 described in FIG. 14. In step 1710, the known good die (e.g., die 800A or 1000A) is bonded to the wafer (e.g., wafer 200 or 300), forming a stacked semiconductor structure (e.g., stacked semiconductor structure 1200 or 1300), as described above with reference to FIG. 12 or 13. In step 1712, a test is performed with a tester (e.g., tester 824), as described above with reference to FIG. 13.

Example embodiments of the disclosure are described below. Other embodiments can also be understood from the entirety of the specification as well as the claims filed herein.

Example 1. A method including forming a first die in a first wafer. The first die includes first bond pads and one or more first test pads on a first side of the first die and a first capping layer over each of the one or more first test pads. The method further includes contacting at least one first capping layer with one or more first test probes to perform a first test, identifying the first die as a known good die based on a result of the first test, and removing at least a portion of each first capping layer.

Example 2. The method of example 1, where removing at least the portion of each first capping layer includes performing an atomic layer etch process.

Example 3. The method of one of examples 1 and 2, where forming the first capping layer over each of the one or more first test pads includes selectively depositing a conductive material on the one or more test pads.

Example 4. The method of one of examples 1 to 3, where the first capping layer includes a native oxide.

Example 5. The method of one of examples 1 to 4, where the first die further includes the first capping layer over each of the first bond pads.

Example 6. The method of one of examples 1 to 5, further including bonding the known good die to a second wafer, where the second wafer includes second bond pads and second capping layers over the second bond pads, and where the first bond pads are in contact with the second bond pads along a bonding interface.

Example 7. The method of one of examples 1 to 6, where the one or more first test pads are within a footprint defined by an extent of the bonding interface between the known good die and the second wafer.

Example 8. The method of one of examples 1 to 7, where the first capping layer has a hardness greater than a hardness of the first bond pads or the one or more first test pads.

Example 9. The method of one of examples 1 to 8, wherein the first capping layer includes Ru.

Example 10. A method including forming a first bonding layer on a first side of a first wafer. The first bonding layer includes a first dielectric layer and first bond pads embedded in the first dielectric layer. First capping layers are formed on the first bond pads. A hardness of the first capping layer is greater than a hardness of the first bond pads. A second bonding layer is formed on a first side of a second wafer. The second bonding layer includes a second dielectric layer and second bond pads embedded in the second dielectric layer. Second capping layers are formed on the second bond pads. A hardness of the second capping layer is greater than a hardness of the second bond pads. The first wafer is hybrid bonded to the second wafer.

Example 11. The method of example 10, where each of the first capping layers is in physical contact with a respective one of the second capping layers.

Example 12. The method of one of examples 10 and 11, wherein each of the first capping layers includes a first native oxide layer and each of the second capping layers includes a second native oxide layer.

Example 13. The method of example 12, where the first native oxide layer and the second native oxide layer are conductive layers.

Example 14. The method of one of examples 10 to 13, where forming the first capping layers on the first bond pads includes: forming a first deposition inhibitor layer on a top surface of the first dielectric layer; selectively depositing a first conductive material on top surfaces of the first bond pads; and removing the first deposition inhibitor layer from the top surface of the first dielectric layer.

Example 15. The method of one of examples 10 to 14, where the first capping layers and the second capping layers include Ru.

Example 16. A method including providing a first substrate having a test pad, selectively depositing a capping layer over the test pad, and bonding the first substrate to a second substrate. The second substrate covers the test pad.

Example 17. The method of example 16, where the capping layer includes ruthenium (Ru).

Example 18. The method of example 17, further including oxidizing the capping layer to from a conductive Ru oxide.

Example 19. The method of one of examples 16 to 18, further including selectively removing the capping layer using an atomic layer etch process before bonding the first substrate to the second substrate.

Example 20. The method of one of examples 16 to 19, where a hardness of the capping layer is greater than a hardness of the test pad.

Example 21. A method including forming a first dielectric layer and first bond pads on a first substrate, forming a second dielectric layer and second bond pads on a second substrate, forming a ruthenium (Ru) capping layer over the first bond pads, the second bond pads, or both the first and second bond pads, and bonding the first substrate to the second substrate.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

“Substrate,” “target substrate,” “structure,” or “device” as used herein generically refers to an object being processed in accordance with the disclosure, and may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate, structure, or device is not limited to any particular base structure, underlying layer or overlying layer, patterned or un-patterned, but rather, is contemplated to include any such layer or base structure, and any combination of layers and/or base structures. The description may reference particular types of substrates, structures, or devices, but this is for illustrative purposes only.

Although this disclosure describes particular process steps as occurring in a particular order, this disclosure contemplates the process steps occurring in any suitable order. While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
forming a first die in a first wafer, wherein the first die comprises:
first bond pads and one or more first test pads on a first side of the first die; and
a first capping layer over each of the one or more first test pads;
contacting at least one first capping layer with one or more first test probes to perform a first test;
identifying the first die as a known good die based on a result of the first test; and
removing at least a portion of each first capping layer.

2. The method of claim 1, wherein removing at least the portion of each first capping layer comprises performing an atomic layer etch process.

3. The method of claim 1, wherein forming the first capping layer over each of the one or more first test pads comprises selectively depositing a conductive material on the one or more test pads.

4. The method of claim 1, wherein the first capping layer comprises a native oxide.

5. The method of claim 1, wherein the first die further comprises the first capping layer over each of the first bond pads.

6. The method of claim 1, further comprising bonding the known good die to a second wafer, wherein the second wafer comprises second bond pads and second capping layers over the second bond pads, and wherein the first bond pads are in contact with the second bond pads along a bonding interface.

7. The method of claim 6, wherein the one or more first test pads are within a footprint defined by an extent of the bonding interface between the known good die and the second wafer.

8. The method of claim 1, wherein the first capping layer has a hardness greater than a hardness of the first bond pads or the one or more first test pads.

9. The method of claim 1, wherein the first capping layer comprises Ru.

10. A method comprising:
forming a first bonding layer on a first side of a first wafer, wherein the first bonding layer comprises a first dielectric layer and first bond pads embedded in the first dielectric layer;
forming first capping layers on the first bond pads, wherein a hardness of the first capping layer is greater than a hardness of the first bond pads;
forming a second bonding layer on a first side of a second wafer, wherein the second bonding layer comprises a second dielectric layer and second bond pads embedded in the second dielectric layer;
forming second capping layers on the second bond pads, wherein a hardness of the second capping layer is greater than a hardness of the second bond pads; and
hybrid bonding the first wafer to the second wafer.

11. The method of claim 10, wherein each of the first capping layers is in physical contact with a respective one of the second capping layers.

12. The method of claim 10, wherein each of the first capping layers includes a first native oxide layer and each of the second capping layers includes a second native oxide layer.

13. The method of claim 12, wherein the first native oxide layer and the second native oxide layer are conductive layers.

14. The method of claim 10, wherein forming the first capping layers on the first bond pads comprises:
forming a first deposition inhibitor layer on a top surface of the first dielectric layer;
selectively depositing a first conductive material on top surfaces of the first bond pads; and
removing the first deposition inhibitor layer from the top surface of the first dielectric layer.

15. The method of claim 10, wherein the first capping layers and the second capping layers comprise Ru.

16. A method comprising:
providing a first substrate having a test pad;
selectively depositing a capping layer over the test pad; and
bonding the first substrate to a second substrate, the second substrate covering the test pad.

17. The method of claim 16, wherein the capping layer comprises ruthenium (Ru).

18. The method of claim 17, further comprising oxidizing the capping layer to from a conductive Ru oxide.

19. The method of claim 16, further comprising selectively removing the capping layer using an atomic layer etch process before bonding the first substrate to the second substrate.

20. The method of claim 16, wherein a hardness of the capping layer is greater than a hardness of the test pad.

21. A method comprising:
forming a first dielectric layer and first bond pads on a first substrate;
forming a second dielectric layer and second bond pads on a second substrate;
forming a ruthenium (Ru) capping layer over the first bond pads, the second bond pads, or both the first and second bond pads; and
bonding the first substrate to the second substrate.
